(19) United States
(12) Patent Application Publication
(10) Pub. No.: US 2026/0358065 A1
(43) Pub. Date: Nov. 12, 2026

(54) HEAT DISSIPATION SUBSTRATE AND HEAT DISSIPATION DEVICE

(71) Applicant: KYOCERA CORPORATION, Kyoto-shi, Kyoto (JP)

(72) Inventor: Takashi MIYAMOTO, Kagoshima-shi, Kagoshima (JP)

(73) Assignee: KYOCERA CORPORATION, Kyoto-shi, Kyoto (JP)

(21) Appl. No.: 19/121,699

(22) PCT Filed: Oct. 12, 2023
(86) PCT No.: PCT/JP2023/036972

§ 371 Date: Apr. 16, 2025

(30) Foreign Application Priority Data
Oct. 17, 2022 (JP) 2022-166067

(51) Int. Cl. F28D 15/02

(52) U.S. Cl. CPC F28D 15/0275

(57) ABSTRACT

A heat dissipation substrate includes a base body and multiple pipe mounting portions. The base body contains a carbon material. The pipe mounting portions are located in the base body. When a direction in which the pipe mounting portions are arranged is called an X direction, a direction in which each of the pipe mounting portions extends is called a Y direction, a plane extending in the X direction and the Y direction is called an XY plane, and a direction intersecting the XY plane is called a Z direction, a thermal conductivity of the base body in the Z direction is higher than a thermal conductivity of the base body in at least one direction along the XY plane.

### TECHNICAL FIELD The present disclosure relates to a heat dissipation substrate and a heat dissipation device.

### BACKGROUND OF INVENTION

A heat dissipation device having a structure in which a pipe body of a heat pipe is held by a heat dissipation substrate is disclosed in Japanese Unexamined Patent Application Publication No. 2010-161177.

### SUMMARY

### Solution to Problem

In the present disclosure, a heat dissipation substrate includes a base and multiple pipe mounting portions.

The base body contains a carbon material.

The pipe mounting portions are located in the base body.

When a direction in which the pipe mounting portions are arranged is called an X direction, a direction in which each of the pipe mounting portions extends is called a Y direction, a plane extending in the X direction and the Y direction is called an XY plane, and a direction intersecting the XY plane is called a Z direction, a thermal conductivity of the base body in the Z direction is higher than a thermal conductivity of the base body in at least one direction along the XY plane.

In the present disclosure, a heat dissipation device includes the above-described heat dissipation substrate and a heat pipe.

The heat pipe includes pipe bodies. The pipe bodies are mounted in the pipe mounting portions.

### BRIEF DESCRIPTION OF THE DRAWINGS

FIG. 1A is a perspective view illustrating a heat dissipation substrate according to Embodiment 1 of the present disclosure.

FIG. 1B is an exploded perspective view illustrating components of the heat dissipation substrate according to Embodiment 1 of the present disclosure.

FIG. 2A is a cross-sectional view taken along line A-A in FIG. 1A.

FIG. 2B is a cross-sectional view taken along line B-B in FIG. 1A.

FIG. 3A is a cross-sectional view illustrating a heat dissipation substrate according to Embodiment 2.

FIG. 3B is a cross-sectional view illustrating a heat dissipation substrate according to Embodiment 3.

FIG. 4A is an exploded perspective view illustrating a heat dissipation substrate according to Embodiment 4.

FIG. 4B is a perspective view illustrating the heat dissipation substrate according to Embodiment 4.

FIG. 5A is a cross-sectional view taken along line A-A in FIG. 4A.

FIG. 5B is a cross-sectional view taken along line B-B in FIG. 4A.

FIG. 6A is a cross-sectional view illustrating a heat dissipation substrate according to Embodiment 5.

FIG. 6B is a cross-sectional view illustrating a heat dissipation substrate according to Embodiment 6.

FIG. 7 is an enlarged cross-sectional view illustrating a heat dissipation substrate according to Embodiment 7.

FIG. 8A is a cross-sectional view illustrating a heat dissipation substrate according to Embodiment 8.

FIG. 8B is a partial enlarged view illustrating the heat dissipation substrate according to Embodiment 8.

FIG. 9A is a side view illustrating a heat dissipation device according to Embodiment 1 of the present disclosure.

FIG. 9B is a side view illustrating a heat dissipation device according to Embodiment 2 of the present disclosure.

### DESCRIPTION OF EMBODIMENTS

Hereinafter, embodiments of the present disclosure will be described in detail with reference to the drawings.

### Embodiment 1

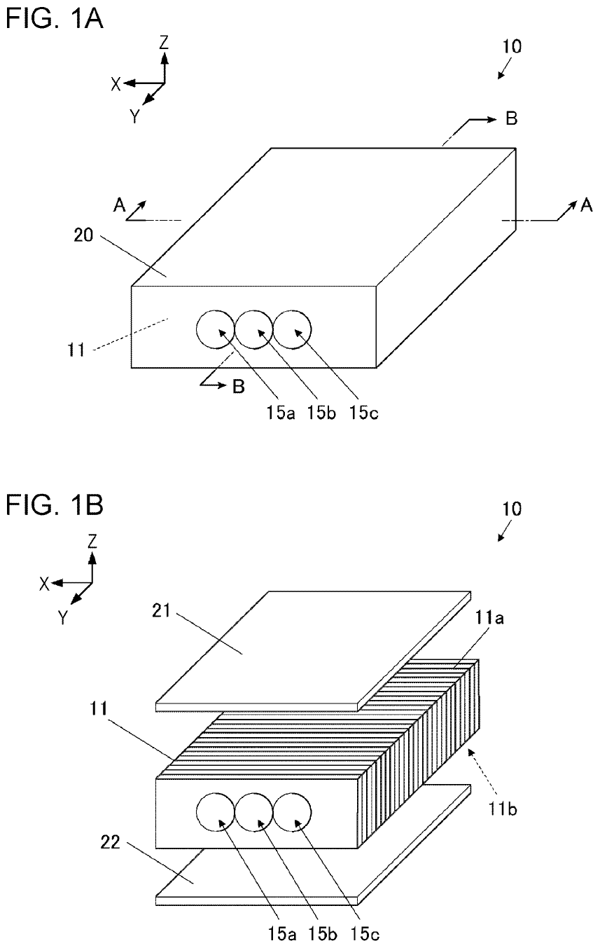

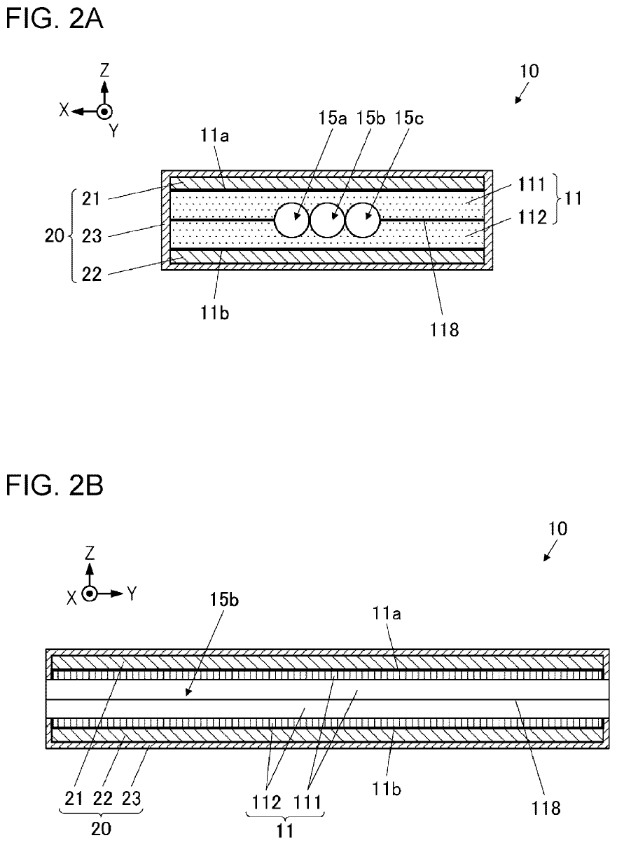

FIG. 1A is a perspective view illustrating a heat dissipation substrate according to Embodiment 1 of the present disclosure and FIG. 1B is an exploded perspective view of components of the heat dissipation substrate. FIGS. 2A and 2B are a cross-sectional view taken along line A-A and a cross-sectional view taken along line B-B in FIG. 1A.

A heat dissipation substrate 10 of Embodiment 1 includes a base body 11 containing a carbon material and pipe mounting portions 15a to 15c located in the base body 11. The heat dissipation substrate 10 may be a substrate that exerts a heat dissipation effect by rapidly transferring heat received from an external heat source to the pipe mounting portions 15a to 15c.

The base body 11 may be a block piece mainly composed of graphite. The term “mainly composed of” may mean a volume ratio of 80% or higher. The base body 11 may be a block piece of graphite having a uniform crystal orientation. The base body 11 may have a structure in which there is a plurality of the above-mentioned block pieces joined together. The graphite may be pyrolytic graphite. The above-mentioned graphite may be highly oriented graphite having a thermal conductivity equivalent to or higher than that of copper or aluminum, and exhibiting anisotropy of thermal conductivity. Processing three-dimensional structures such as the pipe mounting portions 15a to 15c is easier when the base body 11 is a block piece of graphite compared to sheet-like graphite. Furthermore, the base body 11 can support pipe bodies (for example, pipe bodies mounted in the pipe mounting portions 15a to 15c). Furthermore, fixing the base body 11 while a pressure is applied from the base body 11 to a heat source is easier when the base body 11 is a block piece of graphite. The thermal conductivity can be measured using a laser flash method. When graphite has anisotropy of thermal conductivity, “having a thermal conductivity equivalent to or higher than that of copper or aluminum” means having a thermal conductivity equivalent to or higher than that of copper or aluminum in at least one direction. “Having a thermal conductivity equivalent to or higher than that of copper or aluminum” means, for example, that the thermal conductivity is 200 W/m·K or higher, more preferably 370 W/m·K or higher, and even more preferably 450 W/m·K or higher. The graphite used in this embodiment may have a thermal conductivity of 800 W/m·K or higher in one direction.

The heat dissipation substrate 10 may further include a cover member 20 located on the outer surfaces of the base body 11. The base body 11 may include, as the outer surfaces, a first surface 11a, a second surface 11b located on an opposite side from the first surface 11a, and a plurality of side surfaces that are smaller than the first surface 11a and the second surface 11b. The cover member 20 may be located on multiple outer surfaces of the base body 11 (i.e., the first surface 11a, the second surface 11b, and multiple side surfaces), excluding the pipe mounting portions 15a to 15c. By including the cover member 20, even if the strength of outer surface portions of the base body 11 is low, the strength can be compensated for by the cover member 20. Therefore, by including the cover member 20, the freedom with which a material can be selected for the base body 11 is improved, and a material that can further improve heat dissipation performance can be adopted.

The thermal conductivity of the base body 11 may be higher than the thermal conductivity of the cover member 20. With this configuration, high heat diffusibility is obtained in the base body 11, and the heat dissipation performance of the heat dissipation substrate 10 can be improved. When the thermal conductivity of the base body 11 exhibits anisotropy, the thermal conductivity of the base body 11 in at least the Z direction, described later, may be higher than that of the cover member 20. With this configuration, the thermal conductivity in a direction from the second surface 11b of the heat dissipation substrate 10 toward the pipe mounting portions 15a to 15c is improved, and the heat dissipation performance of the heat dissipation substrate 10 can be improved.

The cover member 20 may be composed of metal. With this configuration, the thermal conductivity of the cover member 20 can also be improved and a reduction in the heat dissipation performance of the heat dissipation substrate 10 caused by the cover member 20 can be reduced. The cover member 20 may include metal plating. With the metal plating, the cover member 20 can cover the fine structure of the base body 11, and reduce the release of fragments of the outer surface of the base body 11 that has been damaged to the outside. Therefore, there is no need to increase the hardness of the base body 11, and the freedom in terms of what material is used is improved. The thermal conductivity of the cover member 20 may be 90 W/m·K or higher. When the thermal conductivity of the cover member 20 is 90 W/m·K or higher, the reduction in the heat dissipation performance of the heat dissipation substrate 10 caused by the cover member 20 can be further reduced.

More specifically, the cover member 20 may include a first plate 21 located on the first surface 11a of the base body 11, a second plate 22 located on the second surface 11b of the base body 11, and metal plating 23 located on an outer peripheral surface of a combined structure consisting of the base body 11, the first plate 21, and the second plate 22. The first plate 21 and the second plate 22 provide high strength to upper and lower surface portions of the heat dissipation substrate 10, and this allows the heat dissipation substrate 10 to be easily fixed in place while pressing the upper or lower surface portion against the heat source. Being fixed in this manner improves the thermal conductivity from the heat source to the heat dissipation substrate 10. Furthermore, the heat dissipation substrate 10 can be easily handled by holding the heat dissipation substrate 10 via the high-strength upper and lower surface portions. Furthermore, since the metal plating 23 is also located on the outside of the first plate 21 and the second plate 22, the metal plating 23 is continuous on the outer peripheral surface of the heat dissipation substrate 10, and peripheral ends of the metal plating 23 are unlikely to appear on the outer peripheral surface, so that peeling of the metal plating 23 can be reduced.

The hardness of the cover member 20 may be higher than the hardness of the base body 11. With this configuration, even if an external force is applied to the cover member 20, the force is dispersed before acting on the base body 11. Therefore, damage to the base body 11 inside the cover member 20 can be reduced. As the hardness, the Vickers hardness may be adopted. The hardness of the cover member 20 may be preferably 10 times or more, more preferably 20 times or more, the hardness of the base body 11. Furthermore, the hardness of the cover member 20 may be preferably a Vickers hardness of 200 MPa or higher, more preferably a Vickers hardness of 500 MPa, and even more preferably a Vickers hardness of 900 MPa or higher. The hardness of the base body 11 may be a Vickers hardness of 10 MPa or higher and 40 MPa or lower. The Vickers hardness can be measured using a measurement method stipulated in JIS (Japanese Industrial Standards) Z 2244:2009.

The first plate 21 and the second plate 22 may be mainly composed of copper or aluminum. Copper or aluminum can be used as the material of the first plate 21 and the second plate 22. Copper has a high thermal conductivity of around 370 W/m·K and good workability, and therefore the cover member 20 would be easy to process. Aluminum has a high thermal conductivity of around 200 W/m·K and is lighter than copper, and therefore a reduction in the weight of the cover member 20 could be achieved. The metal plating 23 may be composed of various metals such as nickel, gold, and silver. The metal plating 23 may consist of a single layer or multiple layers. When the metal plating 23 consists of multiple layers, the layers may be two layers of gold and nickel, for example. In addition, when the metal plating 23 contains gold and nickel, the metal plating 23 may contain an alloy of gold and nickel. The first plate 21 and the second plate 22 may be bonded to the base body 11 via a bonding material such as solder or a thermally conductive resin. With this configuration, as described above, the heat dissipation performance of the heat dissipation substrate 10 can be improved, the strength of the heat dissipation substrate 10 can be improved, damage to the outer surface portions of the base body 11 can be reduced, and external forces applied to the cover member 20 can be dispersed.

The pipe mounting portions 15a to 15c may be each configured to allow mounting of a pipe body included in a heat pipe. The heat dissipation substrate 10 may include multiple pipe mounting portions 15a to 15c, or may include a single pipe mounting portion. The shape of a cross section of the pipe mounting portions 15a to 15c may be a circle, an oval, a rectangle, a polygon, a combination of these shapes, and so on. The cross section may be a vertical cross section (see FIG. 2A) perpendicular to the direction in which the pipe mounting portions 15a to 15c extend. In this embodiment, the number of pipe mounting portions 15a to 15c is three, but is not limited three. The number of pipe mounting portions 15a to 15c may be two or four or more. The number of pipe mounting portions 15a to 15c is preferably three or more. When the number of the pipe mounting portions 15a to 15c is three or more, heat can be dispersed to each of the pipe mounting portions 15a to 15c more readily compared to when the number of the pipe mounting portions is two or less, and therefore heat from the base body 11 can be transferred more efficiently to the pipe bodies mounted in the pipe mounting portions 15a to 15c.

The pipe mounting portions 15a to 15c may be positioned so as to extend across the base body 11 and the cover member 20. Due to parts of the pipe mounting portions 15a to 15c being located in the base body 11, the thermal resistance from the base body 11 to the pipe bodies can be reduced, and heat can be efficiently transmitted to the pipe bodies. Therefore, the heat dissipation performance of the heat dissipation substrate 10 can be improved. Furthermore, as a result of parts of the pipe mounting portions 15a to 15c being located in the cover member 20, the holding strength of the pipe bodies mounted in the pipe mounting portions 15a to 15c can be improved. In Embodiment 1, the pipe mounting portions 15a to 15c penetrate through the metal plating 23, and parts of the pipe mounting portions 15a to 15c are located in the metal plating 23.

Each of the pipe mounting portions 15a to 15c may be a through hole. The pipe mounting portions 15a to 15c that are through holes may be located between the first surface 11a and the second surface 11b of the base body 11 along the first surface 11a of the base body 11. The pipe mounting portions 15a to 15c may also penetrate through the metal plating 23 on the side surfaces of the heat dissipation substrate 10. In other words, the inner surfaces of the pipe mounting portions 15a to 15c are not covered by the cover member 20 (e.g., the metal plating 23), and the base body 11 may be located at the inner surfaces of the pipe mounting portions 15a to 15c before the pipe bodies are mounted. With this configuration, when the pipe bodies are mounted in the pipe mounting portions 15a to 15c, the base body 11, which has high thermal conductivity, is in close proximity to the pipe bodies, and heat can be efficiently transferred from the heat dissipation substrate 10 to the pipe bodies. Furthermore, the pipe bodies cover the inner surfaces of the pipe mounting portions 15a to 15c, and therefore the pipe bodies protect surface portions of the base body 11 exposed at the inner surfaces of the pipe mounting portions 15a to 15c, and damage to the surface of the base body 11 can be reduced.

### <Anisotropy of Thermal Conductivity>

The base body 11 may have anisotropy of thermal conductivity. The anisotropy may be a property in which the thermal conductivity in one of three mutually perpendicular directions is higher than the thermal conductivity in another one of the three directions. In this case, the thermal conductivity in one of the three mutually perpendicular directions may be 100 times or more higher than the thermal conductivity in another one of the three directions. In this case, since the direction of heat conduction can be controlled, heat management becomes easier. More preferably, the anisotropy may be a property in which the thermal conductivity in two of three mutually perpendicular directions is higher than the thermal conductivity in the remaining one of the three mutually perpendicular directions. In this case, the thermal conductivity in two of the three mutually perpendicular directions may be 100 times or more higher than the thermal conductivity in the remaining one of the three mutually perpendicular directions. In this case, heat management becomes even easier. The three directions do not need to be perpendicular to each other, and only need to be in a relationship in which the remaining one direction intersects a plane along two of the directions.

Hereinafter, the direction in which the multiple pipe mounting portions 15a to 15c are arranged is called an X direction, the direction in which each of the multiple pipe mounting portions 15a to 15c extends is called a Y direction, a plane extending in the X direction and the Y direction is called an XY plane, and a direction intersecting (for example, perpendicular to) the XY plane is called a Z direction.

Due to the anisotropy, the thermal conductivity of the base body 11 in the Z direction may be higher than the thermal conductivity in at least one direction along the XY plane of the base body 11. With this configuration, when a heat source is disposed close to the second surface 11b (or the first surface 11a), which has a larger area among the outer surfaces of the base body 11, the heat received from the heat source can be quickly conducted in the Z direction and transferred to the pipe mounting portions 15a to 15c. The pipe bodies quickly absorb the heat, and this further improves the heat dissipation performance of the heat dissipation substrate 10. When the thermal conductivity of the base body 11 in the Z direction is 100 times or more higher than the thermal conductivity in at least one direction along the XY plane of the base body 11, the direction of heat conduction can be more strongly controlled to the Z direction from the heat source toward the pipe mounting portions 15a to 15c. Furthermore, the thermal conductivity of the base body 11 in the Z direction is preferably higher than the thermal conductivity of the base body 11 in the Y direction. In this case, the path along which heat is conducted from the heat source to the pipe bodies can be shortened compared to when the thermal conductivity in the Z direction is equal to or lower than that in the Y direction. Therefore, the heat dissipation substrate 10 can dissipate heat more efficiently.

The thermal conductivity of the base body 11 in the X direction may be higher than the thermal conductivity of the base body 11 in the Y direction. With this configuration, even if heat from the heat source is concentrated in part of the second surface 11b, the heat can be quickly dispersed in the X direction. This action allows the heat to be dispersed and transferred to the multiple pipe mounting portions 15a to 15c arranged in the X direction. Then, the multiple pipe bodies quickly absorb the heat, and thus the heat dissipation performance of the heat dissipation substrate 10 can be further improved. When the thermal conductivity of the base body 11 in the X direction is 100 times or more higher than the thermal conductivity of the base body 11 in the Y direction, heat can be more efficiently dispersed and transferred to the multiple pipe mounting portions 15a to 15c arranged in the X direction.

### Embodiments 2 and 3

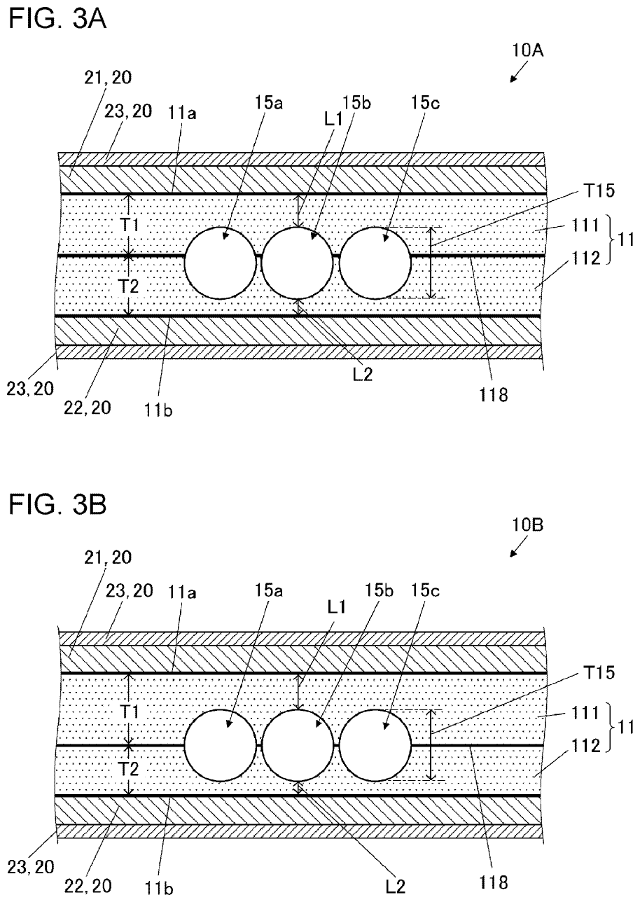

FIG. 3A is a cross-sectional view illustrating a heat dissipation substrate according to Embodiment 2. FIG. 3B is a cross-sectional view illustrating a heat dissipation substrate according to Embodiment 3. Heat dissipation substrates 10A and 10B according to Embodiments 2 and 3 mainly differ with respect to the Z-direction positions of the pipe mounting portions 15a to 15c, which are through holes, and other components thereof may be the same as or similar to those of Embodiment 1.

As in Embodiment 2 (see FIG. 3A) and Embodiment 3 (see FIG. 3B), the pipe mounting portions 15a to 15c, which are through holes, may be positioned so as to be offset from the center of the base body 11 in the Z direction. Specifically, focusing on one pipe mounting portion 15b (corresponding to a first pipe mounting portion) among the multiple pipe mounting portions 15a to 15c, a distance L1 from the pipe mounting portion 15 b to the first surface 11 a and a distance L2 from the pipe mounting portion 15b to the second surface 11b may differ from each other. The “distance” means the length between the closest points. With this configuration, when the surface with the shorter distance (the second surface 11b in FIGS. 3A and 3B) is brought close to a heat source, the thermal resistance from the heat source to the pipe mounting portion 15b can be reduced, and heat can be efficiently transferred to the pipe body. Therefore, the heat dissipation performance of the heat dissipation substrate 10 can be further improved. In addition, the height of the heat dissipation substrate 10 can be ensured by making the distance L1 to the surface on the opposite side (the first surface 11a in FIGS. 3A and 3B) longer. By ensuring the height of the heat dissipation substrate 10, the strength of the heat dissipation substrate 10 can be improved.

The relationship between the distances L1 and L2 may be a relationship that holds true in any vertical cross section in the Y direction, or may be a relationship that holds true in a vertical cross section within a partial range in the Y direction. “Vertical cross section” means a cross section perpendicular to the Y direction. The greater the number of locations where the relationship between the distances L1 and L2 holds true, the greater the range in which the effects realized by the distances L1 and L2 described above can be obtained.

Furthermore, the relationship between the distances L1 and L2 may hold true for only one pipe mounting portion 15b, or may hold true for any or all of the pipe mounting portions 15a to 15c. The more pipe mounting portions 15a to 15c for which the relationship between the distances L1 and L2 holds true, the wider the range across which the effects realized by the distances L1 and L2 described above can be obtained.

The base body 11 in Embodiment 2 and Embodiment 3 may have a configuration including two layers of block pieces 111 and 112. “Layer” means a layer extending in a direction along the X-Y plane. Bonding material 118 may be located between the two layers of block pieces 111 and 112. The bonding material 118 may be solder, a thermally conductive adhesive, a thermally conductive filler (e.g., grease, etc.), or the like. This configuration allows the height of the base body 11 to be easily ensured.

Thicknesses T1 and T2 of the two layers of block pieces 111 and 112 may be the same as each other, as illustrated in FIG. 3A, or may be different from each other, as illustrated in FIG. 3B. In either case, the relationship between the distances L1 and L2 described above can be realized.

When there are the two layers of block pieces 111 and 112, the thicknesses T1 and T2 of the block pieces 111 and 112 may be greater than half a dimension T15 of the pipe mounting portions 15a to 15c in the Z direction. The boundary surface where the bonding material 118 is located may be located at a position halfway along the pipe mounting portions 15a to 15c in the Z direction, or closer to the first surface 11a than that position. With this configuration, the second surface 11b is disposed close to the heat source, and the proportion of the surfaces of the pipe mounting portions 15a to 15c and the block piece 112, which is closer to the heat source, that face each other can be increased. Since the bonding material 118 has a lower thermal conductivity than the block pieces 111 and 112 alone, when heat is conducted in the base body 11 in the Z direction, the heat stagnates at the locations where the bonding material 118 is present. Therefore, with the above configuration, more heat is absorbed by the pipe bodies before stagnation occurs, and the heat dissipation performance of the heat dissipation substrate 10 can be improved.

Even when the two layers of block pieces 111 and 112 are provided, the thermal conductivity in the Z direction may be higher than the thermal conductivity in at least one direction along the XY plane in each of the block pieces 111 and 112. Furthermore, the thermal conductivity in the X direction may be higher than the thermal conductivity in the Y direction. With this configuration, the effect of the anisotropy of the thermal conductivity described in Embodiment 1 is achieved in the same or a similar manner.

### Embodiment 4

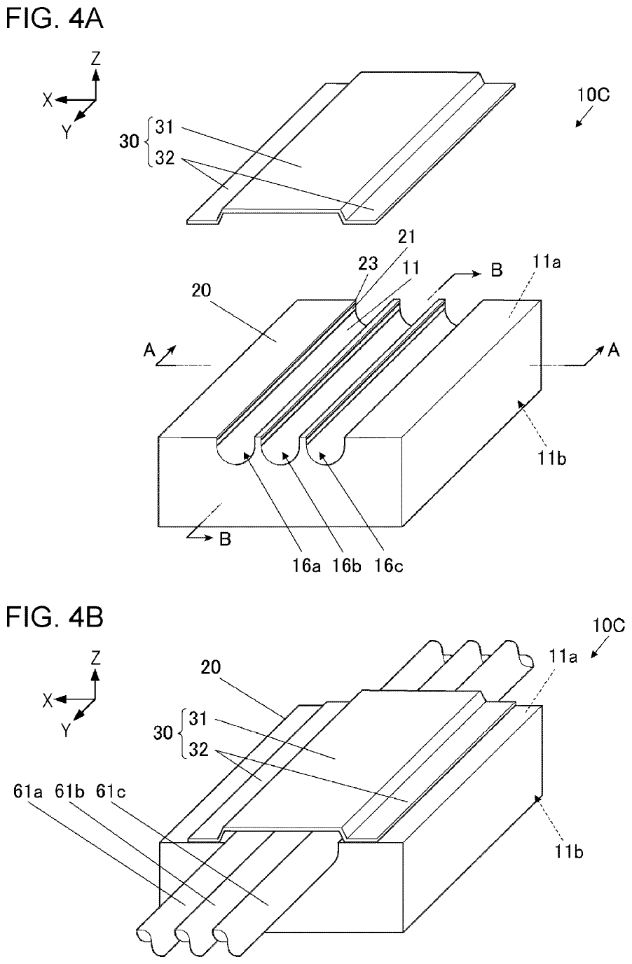

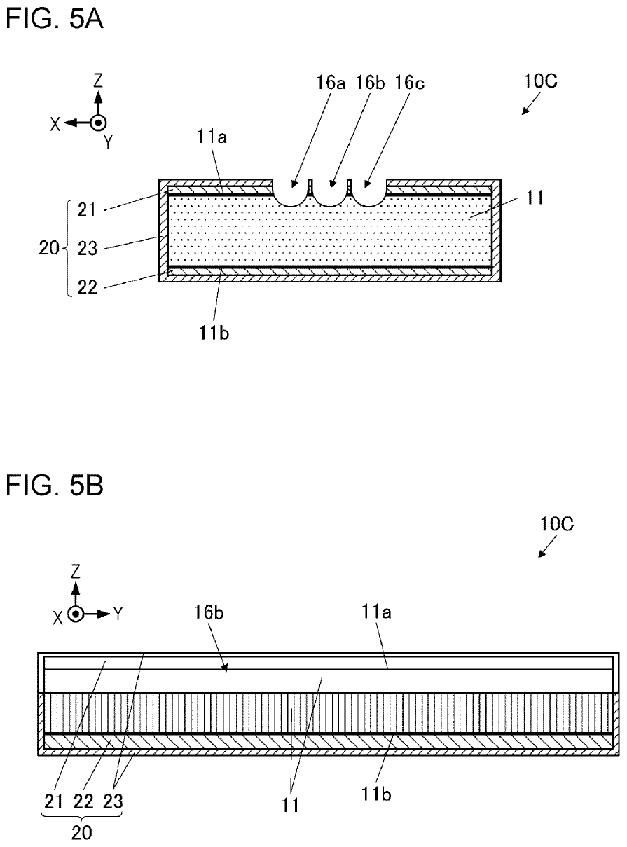

FIGS. 4A and 4B are an exploded perspective view and a perspective view illustrating a heat dissipation substrate according to Embodiment 4. FIGS. 5A and 5B are a cross-sectional view taken along line A-A in FIG. 4A and a cross-sectional view taken along line B-B in FIG. 4A.

A heat dissipation substrate 10C of Embodiment 4 differs mainly in terms of the configuration of pipe mounting portions 16a to 16c. The components of the heat dissipation substrate 10C of Embodiment 4 that are denoted by the same reference symbols as in Embodiment 1 may be the same as or similar to those of the heat dissipation substrate 10 of Embodiment 1 unless otherwise specified.

The pipe mounting portions 16a to 16c included in the heat dissipation substrate 10C may be grooves. The cross-sectional shape of the pipe mounting portions 16a to 16c may be a circular arc, an oval arc, a rectangular shape, a polygonal shape including a V-shape, and so on. The term “cross-section” may refer to a vertical cross-section perpendicular to the direction in which the pipe mounting portions 16a to 16c extend. As a result of the pipe mounting portions 16a to 16c being grooves, the process of combining pipe bodies with the heat dissipation substrate 10C can be simplified.

The pipe mounting portions 16a to 16c may be located on the first surface 11a side of the base body 11. With this arrangement, the second surface 11b side can be made flat while the pipe bodies are mounted in the pipe mounting portions 16a to 16c, and therefore the heat source can be more easily brought close to the second surface 11b side. Therefore, the distance between the heat source and the pipe mounting portions 16a to 16c can be reduced, and the thermal resistance from the heat source to the pipe mounting portions 16a to 16c can be reduced.

The pipe mounting portions 16a to 16c may be positioned so as to extend across the base body 11 and the cover member 20. That is, as illustrated in FIG. 5A, in a vertical cross section perpendicular to the direction in which the pipe mounting portions 16a to 16c extend, the cover member 20 located at the surface layer may be divided by the pipe mounting portions 16a to 16c (for example, grooves). The base body 11 located under the cover member 20 may be located (e.g., exposed) at the bottom of the pipe mounting portions 16a to 16c (e.g., bottom of the grooves). By positioning the base body 11 on at least part of the inner surfaces of the pipe mounting portions 16a to 16c, the base body 11, which has high thermal conductivity, and the pipe bodies can be brought into close proximity to each other, and heat can be efficiently transferred from the base body 11 to the pipe bodies. This improves the heat dissipation performance of the heat dissipation substrate 10C.

Hereinafter, the direction in which the multiple pipe mounting portions 16a to 16c are arranged is called an X direction, the direction in which each of the multiple pipe mounting portions 16a to 16c extends is called a Y direction, a plane extending in the X direction and the Y direction is called an XY plane, and a direction intersecting (e.g., perpendicular to) the XY plane is called a Z direction.

The thermal conductivity of the base body 11 in the Z direction may be higher than the thermal conductivity of the base body 11 in at least one direction along the XY plane. With this configuration, the heat of the heat source received from the second surface 11b side can be quickly conducted in the Z direction and transferred to the pipe mounting portions 16a to 16c. The pipe bodies quickly absorb the heat, and therefore the heat dissipation performance of the heat dissipation substrate 10C can be further improved.

The thermal conductivity of the base body 11 in the X direction may be higher than the thermal conductivity of the base body 11 in the Y direction. With this configuration, even if heat from the heat source is concentrated in part of the second surface 11b, the heat can be quickly dispersed in the X direction. With this action, the heat can be dispersed and transferred to the multiple pipe mounting portions 16a to 16c arranged in the X direction. The multiple pipe bodies quickly absorb the heat, and consequently, the heat dissipation performance of the heat dissipation substrate 10C can be further improved.

The pipe mounting portions 16a to 16c, which are grooves, may be positioned from one end to the other end of the heat dissipation substrate 10C in the Y direction. Alternatively, the pipe mounting portions 16a to 16c, which are grooves, may be positioned only in a partial range in the Y direction. For example, the pipe mounting portions 16a to 16c, which are grooves, may be positioned only in a central region in the Y direction, and the pipe bodies may be mounted so as to be in contact with or separated from the upper surface of the heat dissipation substrate 10C at one end and the other end thereof in the Y direction. Alternatively, pipe mounting portions 16a to 16c that are grooves and pipe mounting portions 16a to 16c that are through holes may be connected to each other in the Y direction, and the pipe bodies may be mounted so as to extend across the grooves and through holes. Note that the upward direction does not need to match the vertical relationship in the actual state of use. The upward direction is, for example, the direction from the second surface 11b to the first surface 11a of the heat dissipation substrate 10C in the Z direction.

Pipe bodies 61a to 61c may be bonded to the pipe mounting portions 16a to 16c via a bonding material such as solder or a thermally conductive adhesive, or may be positioned with a thermally conductive filler (e.g., grease) therebetween.

The heat dissipation substrate 10C may include a metal plate 30 (see FIG. 4A) that covers at least part of the pipe mounting portions 16a to 16c from above. The metal plate 30 holds the pipe bodies 61a to 61c by sandwiching the pipe bodies 61a to 61c mounted in the pipe mounting portions 16a to 16c from above. In addition, the metal plate 30 may have a function of receiving heat from the cover member 20 and transferring the heat to the pipe bodies 61a to 61c as a result of being close to the upper parts of the pipe bodies 61a to 61c of the heat dissipation substrate 10C. With this configuration, heat can be transferred to the pipe bodies 61a to 61c on the opposite side of the pipe mounting portions 16a to 16c, so that the heat dissipation performance of the heat dissipation substrate 10C can be improved even if the pipe mounting portions 16a to 16c are grooves.

The material of the metal plate 30 may mainly consist of copper, aluminum, or the like. Copper has a high thermal conductivity of around 370 W/m·K and good workability, and therefore the cover member 20 would be easy to process. Aluminum has a high thermal conductivity of around 200 W/m·K and is lighter than copper, and therefore a reduction in the weight of the cover member 20 could be achieved.

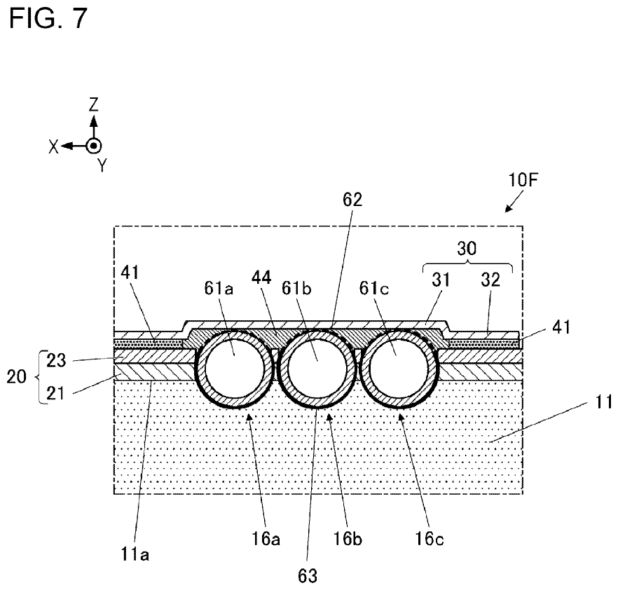

The metal plate 30 may include a main body 31 located above the pipe mounting portions 16a to 16c and flange portions 32 connected to peripheral portions of the main body 31. The metal plate 30 may be fixed to the cover member 20 by joining the flange portions 32 to the cover member 20. A thermally conductive filler (e.g., grease, etc.) 44 (see FIG. 7) may be located between the main body 31 of the metal plate 30 and the pipe bodies 61a to 61c. This configuration allows the process of mounting the pipe bodies 61a to 61c and the process of fixing the metal plate 30 to be simplified.

### Embodiment 5

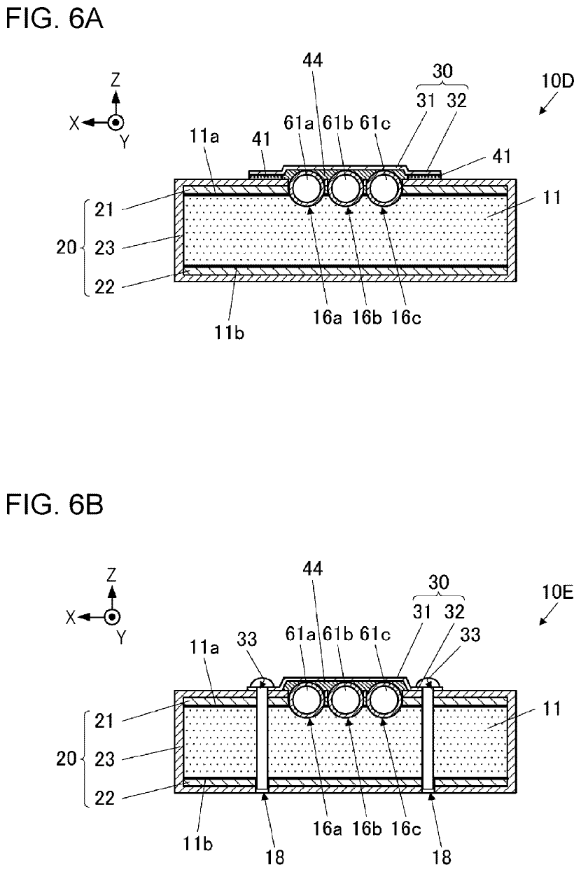

FIG. 6A is a cross-sectional view illustrating a heat dissipation substrate according to Embodiment 5. A heat dissipation substrate 10D of Embodiment 5 may be the same as or similar to that of Embodiment 4, except for the fixing structure of the metal plate 30.

As illustrated in FIG. 6A, the flange portions 32 may be joined to the cover member 20 on the first surface 11a side via a bonding material 41 such as solder or a thermally conductive adhesive. With this configuration, heat conducted to the first surface 11a side via the base body 11 and the cover member 20 can be transferred to the pipe bodies 61a to 61c via the flange portions 32 and the main body 31 of the metal plate 30. Therefore, even if the pipe mounting portions 16a to 16c are grooves and parts (e.g., the upper parts) of the pipe bodies 61a to 61c are separated from the base body 11 or the cover member 20, heat can be absorbed from the separated parts. Thus, the heat dissipation performance of the heat dissipation substrate 10C can be further improved.

### Embodiment 6

FIG. 6B is a cross-sectional view illustrating a heat dissipation substrate according to Embodiment 6. A heat dissipation substrate 10E of Embodiment 6 may be the same as or similar to that of Embodiment 4, except that the fixing structure of the metal plate 30 is different.

As illustrated in FIG. 6B, the flange portions 32 may be screwed to a combined structure consisting of the base body 11 and the cover member 20. That is, the combined structure consisting of the base body 11 and the cover member 20 may include screw holes 18 in portions overlapping the flange portions 32, and the flange portions 32 may include screw holes 33 at corresponding positions. The screw holes 18 may include a female thread at the position of the second plate 22 or the position of the first plate 21. The screw holes 18 may penetrate through the base body 11 and the cover member 20 from the first surface 11a side to the second surface 11b side. With this configuration, the metal plate 30 can be fixed in place using screws, and the process of fixing the metal plate 30 can be simplified. Furthermore, the durability of the fixing structure of the metal plate 30 can be improved. In addition, the thermal resistance of connection points between the flange portions 32 and the cover member 20 is reduced, and this contributes to improving the heat dissipation performance of the heat dissipation substrate 10E.

### Embodiment 7

FIG. 7 is an enlarged cross-sectional view illustrating a heat dissipation substrate of Embodiment 7. A heat dissipation substrate 10F of the Embodiment 7 may be the same as or similar to those of Embodiments 4 to 6, except that the positions of the pipe mounting portions 16 a to 16 c, which are grooves, in the Z direction (i.e., in the depth direction) are different. FIG. 7 illustrates an example in which the joining structure of the metal plate 30 of Embodiment 5 is adopted, but the joining structure of Embodiment 6 may also be adopted.

The pipe bodies 61a to 61c are mounted in the pipe mounting portions 16a to 16c. As illustrated in FIG. 7, in a vertical cross section, the length of facing portions 63 where the pipe bodies 61a to 61c face the base body 11 and the cover member 20 may be greater than the length of facing portions 62 where the pipe bodies 61a to 61c face the metal plate 30. In FIG. 7, the facing portions 62 and 63 are indicated by thick dashed lines and thick solid lines, respectively. The above-mentioned vertical cross section refers to a cross section taken at a location where the pipe mounting portions 16a to 16c are covered by the metal plate 30, and is perpendicular to the direction in which the pipe mounting portions 16a to 16c extend. When a heat source is close to the second surface 11b side, the path along which heat is transferred from the heat source to the pipe bodies 61a to 61c via the base body 11 and the cover member 20 has a smaller thermal resistance than the path along which heat is transferred via the metal plate 30. Therefore, the size relationship between the above-mentioned facing portions 62 and 63 can allow the overall thermal resistance from the heat source to the pipe bodies 61a to 61c to be reduced, and allow heat to be efficiently transferred to the pipe bodies 61a to 61c. Therefore, the heat dissipation performance of the heat dissipation substrate 10F can be further improved.

The size relationship between the above-mentioned facing portions 62 and 63 may be a relationship that holds true from one end to the other end of the metal plate 30 in the Y direction, or may be a relationship that holds true only in a partial range. The greater the number of locations where the size relationship between the facing portions 62 and 63 holds true, the greater the range across which the above-mentioned effects can be obtained.

### Embodiment 8

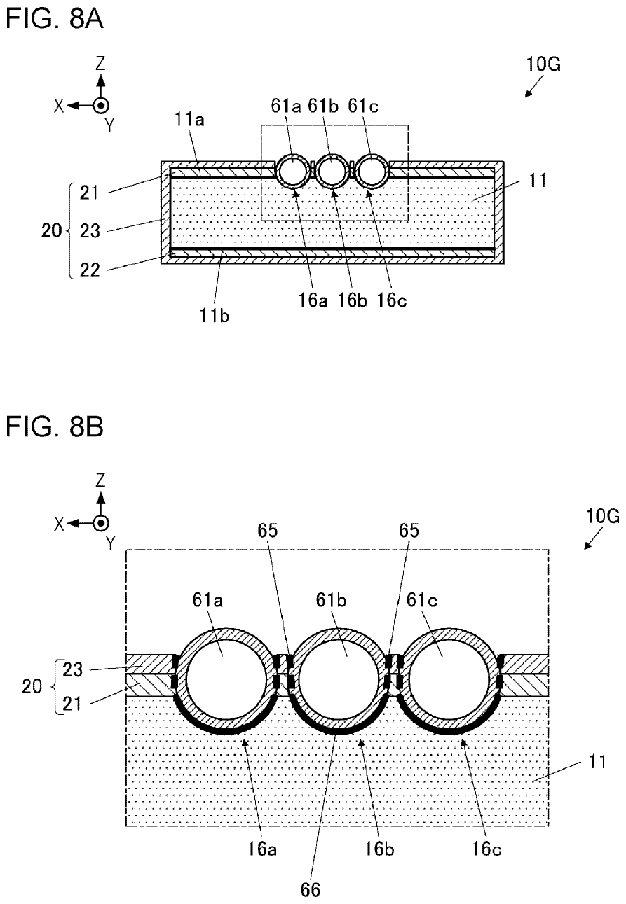

FIG. 8A and FIG. 8B are a cross-sectional view and a partial enlarged view illustrating a heat dissipation substrate of Embodiment 8. A heat dissipation substrate 10G of Embodiment 8 may be the same as or similar to that of Embodiments 4 to 7 except that the positions of the pipe mounting portions 16a to 16c, which are grooves, in the Z direction (i.e., the depth direction) are different. In FIG. 8, the metal plate 30 is omitted, but the configuration and fixing structure of the metal plate 30 may be the same as or similar to those of Embodiments 4 to 7.

As illustrated in FIG. 8, in the vertical cross section, the length of facing portions 66 where the pipe bodies 61a to 61c face the base body 11 may be longer than the length of facing portions 65 where the pipe bodies 61a to 61c face the cover member 20. In FIG. 8, the facing portions 65 and 66 are indicated by thick dashed lines and thick solid lines, respectively. The above-mentioned vertical cross section refers to a cross section taken at a location where the pipe mounting portions 16a to 16c are covered by the metal plate 30, and is perpendicular to the direction in which the pipe mounting portions 16a to 16c extend. Since the thermal conductivity of the base body 11 is higher than the thermal conductivity of the cover member 20, when a heat source is close to the second surface 11b side, the thermal conduction path from the heat source to the pipe bodies 61a to 61c via the facing portions 66 has a lower thermal resistance than the thermal conduction path via the cover member 20 and the facing portions 65. Therefore, the size relationship between the facing portions 65 and 66 allows the overall thermal resistance from the heat source to the pipe bodies to be reduced and the heat dissipation performance of the heat dissipation substrate 10G to be further improved.

The size relationship between the facing portions 65 and 66 may be a relationship that holds true in any vertical cross section from one end to the other end of the base body 11 in the Y direction, or may be a relationship that holds true in at least one location from the one end to the other end. The greater the number of locations where the size relationship between the facing portions 65 and 66 holds true, the greater the range across which the above-mentioned effects can be obtained.

### (Heat Dissipation Device)

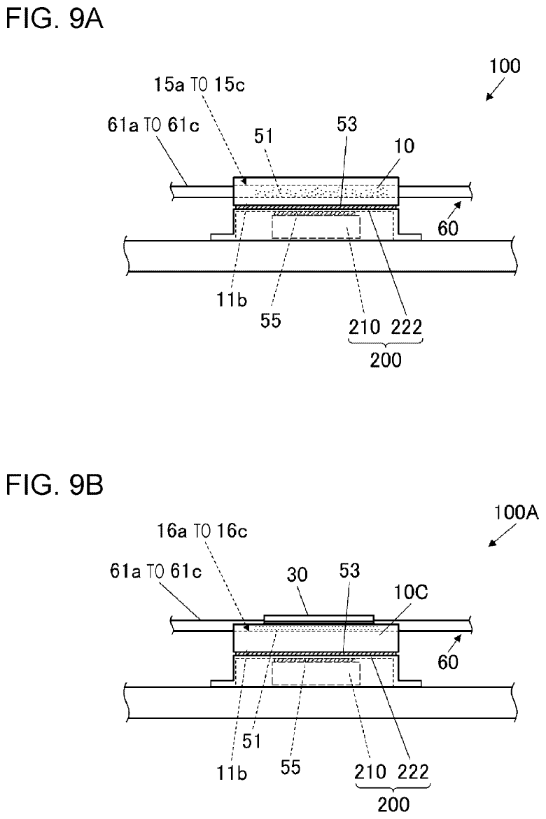

FIG. 9A is a side view of a heat dissipation device according to Embodiment 1 of the present disclosure. FIG. 9B is a side view of a heat dissipation device of Embodiment 2 of the present disclosure. FIGS. 9A and 9B illustrate a state in which heat dissipation devices 100 and 100A are mounted on a heat-generating electronic device (e.g., a CPU (central processing unit) 200).

The heat dissipation device 100 of Embodiment 1 includes the heat dissipation substrate 10 of Embodiment 1 described above and a heat pipe 60. The heat pipe 60 include the pipe bodies 61a to 61c, and the pipe bodies 61a to 61c are mounted in the pipe mounting portions 15a to 15c. The heat dissipation substrate 10 may be replaced with the heat dissipation substrate 10A and 10B of Embodiments 2 and 3.

The heat dissipation device 100A of Embodiment 2 includes the heat dissipation substrate 10C of Embodiment 4 described above and the heat pipe 60. The heat pipe 60 includes the pipe bodies 61a to 61c. The pipe bodies 61a to 61c are mounted in the pipe mounting portions 16a to 16c and are partially covered by the metal plate 30. The heat dissipation substrate 10C may be replaced by the heat dissipation substrates 10D to 10G of Embodiments 5 to 8.

The heat dissipation devices 100 and 100A may further include a heat sink thermally connected to the heat pipe 60 and/or a cooling mechanism (e.g., a cooling fan, a coolant circuit, etc.).

In the heat dissipation devices 100 and 100A, the outer surface of the base body 11 of the heat dissipation substrates 10 and 10C may be covered by the cover member 20, and the inner surfaces of the pipe mounting portions 15a to 15c and 16a to 16c may be covered by the pipe bodies 61a to 61c. With this configuration, the outer surface of the base body 11 is not exposed to the outside. Therefore, even if a material that has high thermal conductivity but does not necessarily need the hardness of the outer surface to be improved is used as the base body 11, the outer surface of the base body 11 can be protected and damage to the base body 11 can be reduced.

The pipe bodies 61a to 61c may be composed of metal. A thermally conductive filler 51 may be filled between the outer peripheral surfaces of the pipe bodies 61a to 61c and the inner surfaces of the pipe mounting portions 15a to 15c and 16a to 16c. As the filler 51, a hardening material (i.e., a bonding material) such as solder or a thermally conductive resin adhesive may be applied, or a non-hardening material such as thermally conductive grease may be applied.

The electronic device 200 may include a semiconductor element 210 and a heat spreader 222. Furthermore, the heat spreader 222 may function as a package for accommodating the semiconductor element 210. The heat spreader 222 may be in surface contact with the semiconductor element 210 via thermally conductive grease 55 or the like.

The heat dissipation devices 100 and 100A may be mounted such that the second surface 11b side of the heat dissipation substrate 10 is in surface contact with the heat spreader 222 via thermally conductive grease 53.

The heat dissipation devices 100 and 100A having the above-described configurations receive heat from the heat-generating electronic device 200 via the heat dissipation substrates 10 and 10C, efficiently transfer the heat to the heat pipe 60 in the heat dissipation substrates 10 and 10C, and dissipate the heat to the outside through the heat pipe 60. Therefore, high heat dissipation performance can be achieved for the electronic device 200, which generates a large amount of heat.

Embodiments of the present disclosure have been described above, but a heat dissipation substrate and a heat dissipation device of the present disclosure are not limited to the above embodiments. For example, in the above embodiments, the first plate 21 and second plate 22 composed of metal and the metal plating 23 are depicted as constituting the cover member 20, but the first plate 21 and the second plate 22 may be omitted and the metal plating may be used as the cover member. In addition, film-like or plate-like resin may be used as the cover member. Other details described in the embodiments can be changed as appropriate.

Hereinafter, an embodiment of the present disclosure is described. In an embodiment,
(1) a heat dissipation substrate includes:
   a base body containing a carbon material; and
   multiple pipe mounting portions located in the base body, and
   when a direction in which the pipe mounting portions are arranged is called an X direction, a direction in which each of the pipe mounting portions extends is called a Y direction, a plane extending in the X direction and the Y direction is called an XY plane, and a direction intersecting the XY plane is called a Z direction,
   a thermal conductivity of the base body in the Z direction is higher than a thermal conductivity of the base body in at least one direction along the XY plane.
(2) In the heat dissipation substrate of (1) above,
   a thermal conductivity of the base body in the X direction is higher than a thermal conductivity of the base body in the Y direction.
(3) In the heat dissipation substrate of (1) or (2) above,
   the base body has a first surface located on one side in the Z direction and a second surface located on another side in the Z direction,
   the pipe mounting portions include a first pipe mounting portion, and
   a distance from the first pipe mounting portion to the first surface is different from a distance from the first pipe mounting portion to the second surface.
(4) In the heat dissipation substrate of any one of (1) to (3) above,
   each of the pipe mounting portions is a through hole.
(5) In the heat dissipation substrate of any one of (1) to (3) above,
   the base body has a first surface located on one side in the Z direction, and
   each of the pipe mounting portions is a groove located in the first surface.
(6) The heat dissipation substrate of (5) above further includes
   a metal plate covering at least part of each of the pipe mounting portions from above the groove.
(7) The heat dissipation substrate of (6) above further includes
   a metal cover member located on an outer surface of the base body, and
   the cover member includes a screw hole that allows the metal plate to be screwed.

In an embodiment,
(8) a heat dissipation device includes
   the heat dissipation substrate of (7), and
   a heat pipe including multiple pipe bodies mounted in the multiple pipe mounting portions, and
   in a vertical cross section of a region where the pipe mounting portions are covered by the metal plate,
   for each of the pipe bodies, a length of a facing portion where the pipe body faces the base body and the cover member is greater than a length of a facing portion where the metal plate faces the pipe body.
(9) In the heat dissipation device of (8) above,
   in the vertical cross section, for each of the pipe bodies, a length of a facing portion where the pipe body faces the base body is greater than a length of a facing portion where the pipe body faces the cover member.
(10) In the heat dissipation device of (8) or (9) above,
   the pipe bodies are composed of metal, and a thermally conductive filler is provided between the pipe bodies and the base body.

### INDUSTRIAL APPLICABILITY

The present disclosure can be used for heat dissipation substrates and heat dissipation devices.

### REFERENCE SIGNS

10, 10A to 10G heat dissipation substrate
11 base body
11a first surface
11b second surface
111, 112 block piece
118 bonding material
15a to 15c, 16a to 16c pipe mounting portion
18 screw hole
20 cover member
21 first plate
22 second plate
23 metal plating
30 metal plate
31 main body
32 flange portion
33 screw hole
41 bonding material
44, 51 filler
60 heat pipe
61a to 61c pipe body
62, 63, 65, 66 facing portion
L1, L2 distance
T1, T2 thickness
100, 100A heat dissipation device
200 electronic device

1. A heat dissipation substrate comprising:
a base body containing a carbon material; and
multiple pipe mounting portions located in the base body,
wherein when a direction in which the pipe mounting portions are arranged is called an X direction, a direction in which each of the pipe mounting portions extends is called a Y direction, a plane extending in the X direction and the Y direction is called an XY plane, and a direction intersecting the XY plane is called a Z direction,
a thermal conductivity of the base body in the Z direction is higher than a thermal conductivity of the base body in at least one direction along the XY plane.

2. The heat dissipation substrate according to claim 1,
wherein a thermal conductivity of the base body in the X direction is higher than a thermal conductivity of the base body in the Y direction.

3. The heat dissipation substrate according to claim 1,
wherein the base body has a first surface located on one side in the Z direction and a second surface located on another side in the Z direction,
the pipe mounting portions include a first pipe mounting portion, and
a distance from the first pipe mounting portion to the first surface is different from a distance from the first pipe mounting portion to the second surface.

4. The heat dissipation substrate according to claim 1,
wherein each of the pipe mounting portions is a through hole.

5. The heat dissipation substrate according to claim 1,
wherein the base body has a first surface located on one side in the Z direction, and
each of the pipe mounting portions is a groove located in the first surface.

6. The heat dissipation substrate according to claim 5, further comprising:
a metal plate covering at least part of each of the pipe mounting portions from above the groove.

7. The heat dissipation substrate according to claim 6, further comprising:
a metal cover member located on an outer surface of the base body,
wherein the cover member includes a screw hole that allows the metal plate to be screwed.

8. A heat dissipation device comprising:
the heat dissipation substrate according to claim 7; and
a heat pipe including multiple pipe bodies mounted in the multiple pipe mounting portions,
wherein in a vertical cross section of a region where the pipe mounting portions are covered by the metal plate,
for each of the pipe bodies, a length of a facing portion where the pipe body faces the base body and the cover member is greater than a length of a facing portion where the metal plate faces the pipe body.

9. The heat dissipation device according to claim 8,
wherein in the vertical cross section, for each of the pipe bodies, a length of a facing portion where the pipe body faces the base body is greater than a length of a facing portion where the pipe body faces the cover member.

10. The heat dissipation device according to claim 8,
wherein the pipe bodies are composed of metal, and a thermally conductive filler is provided between the pipe bodies and the base body.
